(19) United States
(12) Patent Application Publication
(10) Pub. No.: US 2021/0202877 A1
(43) Pub. Date: Jul. 1, 2021

(54) ORGANIC EL ELEMENT, ORGANIC EL DISPLAY PANEL, AND ORGANIC EL ELEMENT MANUFACTURING METHOD

(71) Applicant: JOLED Inc., Tokyo (JP)

(72) Inventor: Kosuke MISHIMA, Tokyo (JP)

(73) Assignee: JOLED Inc., Tokyo (JP)

(21) Appl. No.: 17/131,806

(22) Filed: Dec. 23, 2020

(30) Foreign Application Priority Data
Dec. 27, 2019 (JP) 2019-238723

(51) Int. Cl. H01L 51/50; H01L 27/32; H01L 51/56

(52) U.S. Cl. CPC H01L 51/5056; H01L 51/5088; H01L 27/3218; H01L 51/56; H01L 27/3246

(57) ABSTRACT

An organic electroluminescence (EL) element including an anode, a first functional layer disposed on or above the anode, a light-emitting layer disposed on or above the first functional layer, a second functional layer disposed on or above the light-emitting layer, and a cathode disposed on or above the second functional layer. The first functional layer has at least one of a property of facilitating hole injection and a property of facilitating hole transportation. The light-emitting layer includes an organic light-emitting material doped with an electron donating material. The second functional layer includes a rare earth metal.

### CROSS-REFERENCE TO RELATED APPLICATION

The application claims priority to Japanese Patent Application No. 2019-238723 filed Dec. 27, 2019, the contents of which are hereby incorporated by reference in their entirety.

### BACKGROUND OF THE DISCLOSURE

### Technical Field

The present disclosure relates to organic electroluminescence (EL) elements that make use of electroluminescence of organic materials, organic EL display panels, and organic EL element manufacturing methods.

### Description of the Related Art

In recent years, organic EL display panels in which organic EL elements are arranged in a matrix across a substrate have been put into practical use as light-emitting displays of electronic devices. Each organic EL element has a basic structure of a current-driven light-emitting element in which an organic light-emitting layer including an organic light-emitting material is disposed between a pair of electrodes, an anode and a cathode. When driven, a voltage is applied between the pair of electrodes, and recombination of holes injected to the organic light-emitting layer from the anode and electrons injected to the organic light-emitting layer from the cathode causes light emission.

In such organic EL elements, improvements in luminance efficiency and life extension are always being sought.

An energy level of a lowest unoccupied molecular orbital (LUMO) of an organic material (in particular, a high molecular weight material) of a light-emitting layer is typically different from a Fermi level of a cathode material, and therefore electrons are not smoothly injected from the cathode to the organic light-emitting layer, and good light emission efficiency is difficult to achieve.

Thus, a structure has been proposed in which an organic material that has an electron transporting property for supplying electrons to an organic light-emitting layer is doped with an alkali metal or an alkaline earth metal that has a low work function in order to enhance electron injection (for example, see JP 2016-115748).

### SUMMARY

An organic EL element according to at least one embodiment of the present disclosure is an organic EL element including: an anode; a first functional layer disposed on or above the anode, the first functional layer having at least one of a property of facilitating hole injection and a property of facilitating hole transportation; a light-emitting layer disposed on or above the first functional layer, the light-emitting layer including an organic light-emitting material doped with an electron donating material; a second functional layer disposed on or above the light-emitting layer, the second functional layer including a rare earth metal; and a cathode disposed on or above the second functional layer.

### BRIEF DESCRIPTION OF DRAWINGS

Objects, advantages, and features of the technology pertaining to the present disclosure will become apparent from the following description thereof taken in conjunction with the accompanying drawings, which illustrate at least one embodiment of the technology pertaining to the present disclosure.

FIG. 1 is a block diagram illustrating an overall structure of an organic EL display device according to at least one embodiment.

FIG. 2 is a schematic plan view diagram of an enlargement of a portion of an image display surface of an organic EL panel in the organic EL display device according to at least one embodiment.

FIG. 3 is a schematic cross-section diagram of a cross-section along a line A-A in FIG. 2.

FIG. 4 is a diagram schematically illustrating a layer structure of an organic EL element according to at least one embodiment.

FIG. 5 is a schematic diagram illustrating a state in which energy levels of a hole transport layer, a light-emitting layer, and an electron transport layer are appropriately balanced in the organic EL element according to at least one embodiment.

FIG. 6 is a schematic diagram illustrating an example of a state in which energy levels of a hole transport layer, a light-emitting layer, and an electron transport layer are not appropriately balanced in an organic EL element.

FIG. 7A, 7B, 7C are schematic diagrams for explaining energy levels of hole transport layers, organic light-emitting layers, and second functional layers in organic EL elements.

FIG. 8 is a diagram of simulation results illustrating a relationship between shift amounts of energy levels of light-emitting layers and maximum exciton efficiency in organic EL elements, according to at least one embodiment.

FIG. 9 is a diagram of simulation results illustrating a relationship between shift amounts of energy levels of light-emitting layers and required applied voltage per unit current in organic EL elements, according to at least one embodiment.

FIG. 10 is a diagram of calculation results illustrating a relationship between shift amounts of energy levels of light-emitting layers and n-type carrier density of light-emitting layers in organic EL elements.

FIG. 11 is a diagram of calculation results illustrating a relationship between shift amounts of energy levels of light-emitting layers and a ratio of n-type carrier density of light-emitting layers to carrier density ni of intrinsic semiconductors in organic EL elements.

FIG. 12A is a diagram of experimental results illustrating a relationship between current density and maximum exciton efficiency of light-emitting layers in organic EL elements, and FIG. 12B is a diagram of experimental results illustrating a relationship between applied voltage and current density in the organic EL elements.

FIG. 13 is a flowchart illustrating a process of manufacturing an organic EL display panel according to at least one embodiment.

FIG. 14A to FIG. 14D are cross-section diagrams schematically illustrating a portion of a process of manufacturing organic EL elements.

FIG. 15A to FIG. 15D are cross-section diagrams schematically illustrating a portion of the process of manufacturing organic EL elements, continuing from FIG. 14D.

FIG. 16A and FIG. 16B are cross-section diagrams schematically illustrating a portion of the process of manufacturing organic EL elements, continuing from FIG. 15D.

FIG. 17A to FIG. 17D are cross-section diagrams schematically illustrating a portion of the process of manufacturing organic EL elements, continuing from FIG. 16B.

FIG. 18 is a diagram schematically illustrating a layer structure of an organic EL element according to a modification.

FIG. 19 is a diagram schematically illustrating a layer structure of an organic EL element according to a modification.

FIG. 20 is a diagram schematically illustrating a layer structure of an organic EL element according to a modification.

FIG. 21 is a diagram schematically illustrating a layer structure of an organic EL element according to a modification.

FIG. 22 is a diagram schematically illustrating a layer structure of an organic EL element according to a modification.

FIG. 23 is a diagram schematically illustrating a layer structure of an organic EL element according to a modification.

### DETAILED DESCRIPTION

Even if an electron transport layer doped with an alkali metal or an alkaline earth metal is adopted as described in JP 2016-115748, there is a risk, depending on a material of the organic light-emitting layer, that an energy barrier between the organic light-emitting layer and the electron transport layer is large, such that a quantitative balance (carrier balance) of holes and electrons injected into the organic light-emitting layer is lost, and sufficient luminance efficiency cannot be achieved.

Further, alkali metals and alkaline earth metals have high chemical reactivity and react with impurities remaining inside the organic EL element or impurities such as moisture that enters from outside, leading to deterioration in electron injection and a shortening of life.

In view of the above circumstances, the inventor of the present application arrived at an aspect of the present disclosure as a result of engaging in research with an object of providing an organic EL element having improved luminance efficiency and a longer life.

An organic EL element according to at least one embodiment of the present disclosure is an organic EL element including: an anode; a first functional layer disposed on or above the anode, the first functional layer having at least one of a property of facilitating hole injection and a property of facilitating hole transportation; a light-emitting layer disposed on or above the first functional layer, the light-emitting layer including an organic light-emitting material doped with an electron donating material; a second functional layer disposed on or above the light-emitting layer, the second functional layer including a rare earth metal; and a cathode disposed on or above the second functional layer. Here, “the second functional layer including a rare earth metal” includes a case where the second functional layer is a single layer composed of the rare earth metal.

In the organic EL element according to at least one embodiment, the light-emitting layer is doped with the electron donating material, and therefore an energy barrier between the second functional layer and the light-emitting layer is made smaller, and amounts of holes and electrons injected into the light-emitting layer can be equalized. This improves light emission efficiency. Further, the rare earth metal included in the second functional layer has a small work function, and therefore in addition to facilitating electron injection, the rare earth metal is chemically stable compared to alkali metals and alkaline earth metals, which contributes to an extension in life of the organic EL element.

According to at least one embodiment of the organic EL element, the rare earth metal is Yb.

According to at least one embodiment of the organic EL element, the electron donating material includes one or more metals selected from the group consisting of alkali metals, alkaline earth metals, and rare earth metals.

According to at least one embodiment of the organic EL element, the electron donating material includes Na.

According to at least one embodiment of the organic EL element, the electron donating material includes Yb.

According to at least one embodiment of the organic EL element, the second functional layer is in direct contact with the light-emitting layer.

According to at least one embodiment, the organic EL element further includes an intermediate layer disposed between the light-emitting layer and the second functional layer, the intermediate layer including a metal compound, the metal of the metal compound being selected from the group consisting of alkali metals and alkaline earth metals.

As a result, the metal of the metal compound is reduced by the rare earth metal included in the second functional layer and dissociates, and the dissociated alkali metal or alkaline earth metal improves electron ejection and effectively diffuses into the organic light-emitting material of the organic light-emitting layer.

According to at least one embodiment of the organic EL element, in a film thickness direction of the light-emitting layer, a first region of the light-emitting layer is a region nearest the first functional layer and a second region of the light-emitting layer is a region nearest the second functional layer, and a ratio of the electron donating material to the organic light-emitting material in the first region is smaller than a ratio of the electron donating material to the organic light-emitting material in the second region.

According to at least one embodiment of the organic EL element, a carrier density in the second region of the light-emitting layer is from 10²/cm³ to 10¹⁹/cm³.

By setting the carrier density in the second region of the light-emitting layer to this range, a good carrier balance can be obtained and luminance efficiency is further improved.

According to at least one embodiment of the organic EL element, a density of excitons generated in the light-emitting layer is higher in the first region than in the second region.

As a result, absorption of the energy of excitons generated by recombination of holes and electrons by the electron donating material diffused in the organic light-emitting layer is suppressed, further improving luminance efficiency.

According to at least one embodiment of the organic EL element, the cathode is light-transmissive. According to at least one embodiment of the organic EL element, film thickness of the light-emitting layer is from 30 nm to 150 nm.

This structure facilitates construction of an optical resonator structure, meaning further improvement in luminance efficiency can be expected.

According to at least one embodiment of the organic EL element, at least one layer selected from the group consisting of the light-emitting layer and the first functional layer is a film applied by a wet process.

Manufacturing costs can be reduced by the adoption of a wet process to form the film. When the film is formed by a wet process, a residual amount of impurities such as water is greater than when the film is formed by a dry process, but the rare earth metal included in the second functional layer is relatively chemically stable, and therefore an extension of life can still be expected when compared to conventional use of alkali metals or alkaline earth metals.

According to at least one embodiment of the organic EL element, the first functional layer includes tungsten oxide.

An organic EL display panel according to at least one embodiment includes: a substrate; the organic EL elements according to at least one embodiment arranged on or above the substrate in a matrix of rows and columns; and banks arranged on or above the substrate that extend in a column direction. The banks separate the light-emitting layers of the organic EL elements in a row direction.

An organic EL element manufacturing method according to at least one embodiment includes: forming an anode; forming a first functional layer on or above the anode, the first functional layer having at least one of a property of facilitating hole injection and a property of facilitating hole transportation; forming an organic light-emitting material layer on the first functional layer, the organic light-emitting material layer being made of an organic light-emitting material; forming an intermediate layer on the organic light-emitting material layer, the intermediate layer including a metal compound including a first metal selected from the group consisting of alkali metals and alkaline earth metals; forming a second functional layer on the intermediate layer, the second functional layer including a second metal that is a rare earth metal; and forming a cathode on or above the second functional layer. An electron donating material containing layer is formed from a portion of the organic light-emitting material layer by diffusion of the first metal, or the first metal and the second metal, into the organic light-emitting material layer until a carrier density in the portion of the organic light-emitting material layer is from 10¹²/cm³ to 10¹⁹/cm³.

According to at least one embodiment of the manufacturing method, the metal compound is NaF. According to at least one embodiment of the manufacturing method, the second metal is Yb.

An organic EL element manufacturing method includes: forming an anode; forming a first functional layer on or above the anode, the first functional layer having at least one of a property of facilitating hole injection and a property of facilitating hole transportation; forming an organic light-emitting material layer on the first functional layer, the organic light-emitting material layer being made of an organic light-emitting material; forming a second functional layer on the organic light-emitting material layer, the second functional layer including a rare earth metal; and forming a cathode on or above the second functional layer. An electron donating material containing layer is formed from a portion of the organic light-emitting material layer by diffusion of the first metal, or the first metal and the second metal, into the organic light-emitting material layer until a carrier density in the portion of the organic light-emitting material layer is from 10¹²/cm³ to 10¹⁹/cm³.

According to at least one embodiment of the manufacturing method, the rare earth metal is Yb.

As a result, an organic EL element can be manufactured to have improved luminance efficiency and long life.

An organic EL element, organic EL display panel, and organic EL display device according to various embodiments are described below, with reference to the drawings. The drawings include schematic drawings, and are not necessarily to scale.

### 1. Overall Structure of Organic EL Display Device 1

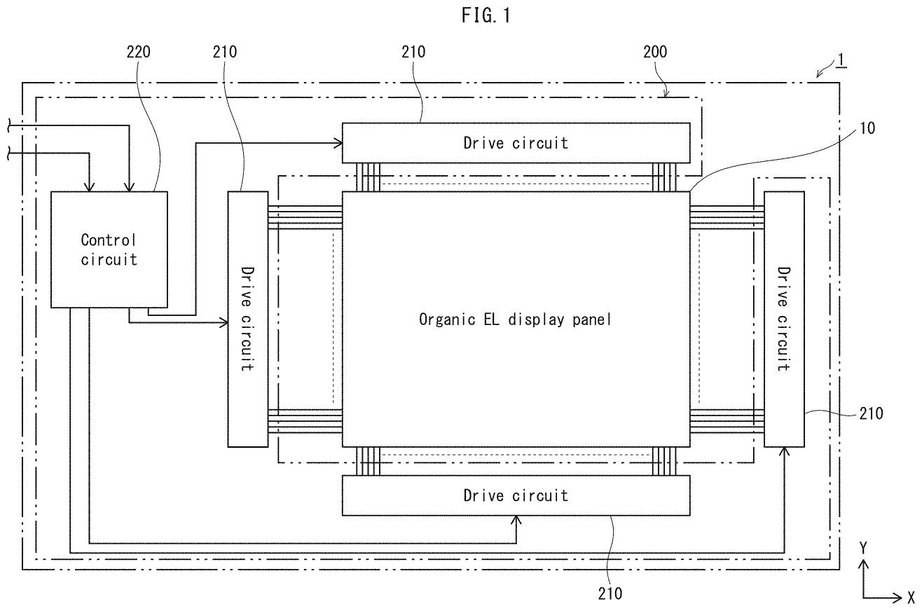

FIG. 1 is a block diagram illustrating an overall structure of an organic EL display device 1. The organic EL display device 1 is a display device used for, for example, a television, a personal computer, a mobile terminal, a commercial display (electronic signboard, large screen for a commercial facility), or the like.

The organic EL display device 1 includes an organic EL display panel 10 and a drive controller 200 electrically connected thereto.

According to at least one embodiment, the organic EL display panel 10 is a top emission type display panel, a top surface of which is a rectangular image display surface. In the organic EL display panel 10, organic EL elements (not illustrated) are arranged along the image display surface, and an image is displayed by combining light emission of the organic EL elements. According to at least one embodiment, the organic EL display panel 10 employs an active matrix.

The drive controller 200 includes drive circuits 210 connected to the organic EL display panel 10 and a control circuit 220 connected to an external device such as a computer or a signal receiver such as an antenna. The drive circuits 210 include a power supply circuit supplying electric power to each of the organic EL elements, a signal circuit for applying a voltage signal for controlling the electric power supplied to each of the organic EL elements, a scanning circuit at regular intervals for switching a position to which the voltage signal is applied, and the like.

The control circuit 220 controls operations of the drive circuits 210 according to data including image information input from the external device or the signal receiver.

In FIG. 1, as an example, four of the drive circuits 210 are disposed around the organic EL display panel 10, but structure of the drive controller 200 is not limited to this example, and the number and position of the drive circuits 210 may be modified as appropriate. In the following explanation, as illustrated in FIG. 1, a direction along a long edge of a top surface of the organic EL display panel 10 is referred to as an X direction and a direction along a short edge of the top surface of the organic EL display panel 10 is referred to as a Y direction.

### 2. Structure of Organic EL Display Panel 10

### (A) Plan View Structure

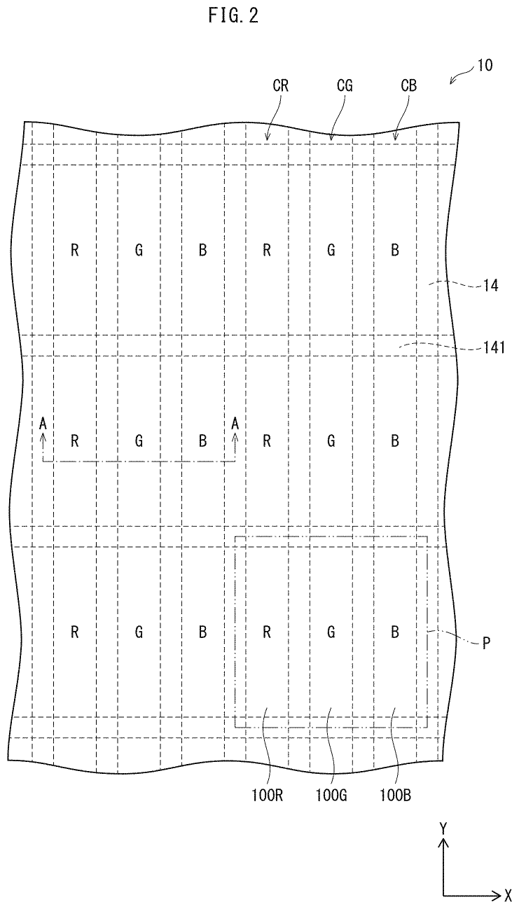

FIG. 2 is a schematic plan view enlargement of a portion of an image display face of the organic EL display panel 10. According to at least one embodiment of the organic EL display panel 10, sub-pixels 100R, 100G, 100B are arranged in a matrix and emit red (R), green (G), and blue (B) colors of light, respectively. The sub-pixels 100R, 100G, 100B are lined up alternating in the X direction, and a set of the sub-pixels 100R, 100G, 100B in the X direction constitute one pixel P. The pixel P can express full color via combinations of graded light emission from the sub-pixels 100R, 100G, 100B.

In addition, in the Y direction, the sub-pixels 100R, the sub-pixels 100G, and the sub-pixels 100B are arranged to form sub-pixel columns CR, sub-pixel columns CG, and sub-pixel columns CB, respectively, in which only the corresponding color of sub-pixel is present. As a result, across the organic EL display panel 10, the pixels P are arranged in a matrix along the X direction and the Y direction, and an image is displayed on the image display face through a combination of colors of light emitted by the pixels P.

Organic EL elements 2(R), 2(G), 2(B) that emit light in the colors R, G, B are disposed in the sub-pixels 100R, 100G, 100B, respectively.

The organic EL display panel 10 according to at least one embodiment employs a line bank structure. That is, the sub-pixel columns CR, CG, CB are partitioned by banks 14 at intervals in the X direction, and in each of the sub-pixel columns CR, CG, CB, the sub-pixels 100R, 100G, or 100B therein share a continuous organic light-emitting layer.

However, in each of the sub-pixel columns CR, CG, CB, pixel regulation layers 141 are disposed at intervals in the Y direction to insulate the sub-pixels 100R, 100G, 100B from each other, such that each of the sub-pixels 100R, 100G, 100B can emit light independently.

Height of the pixel regulation layers 141 is lower than height of a liquid level when organic light-emitting layer ink is applied. In FIG. 2, the banks 14 and the pixel regulation layers 141 are indicated by dotted lines, and this is because the pixel regulation layers 141 and the banks 14 are not exposed on the surface of the image display face and are disposed inside the image display face.

### (B) Cross-Section Structure

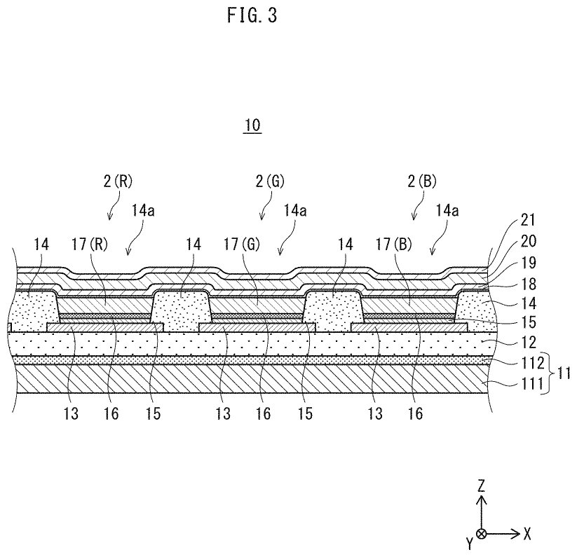

FIG. 3 is a schematic cross-section diagram of a cross-section along a line A-A in FIG. 2. In the organic EL display panel 10, one pixel is composed of three sub-pixels that emit light in the colors R, G, B, and each of the sub-pixels includes a corresponding one of the organic EL elements 2(R), 2(G), 2(B).

The organic EL elements 2(R), 2(G), 2(B) of each light emission color have almost the same structure, and therefore may be described as organic EL elements 2 when not distinguished by color.

As illustrated in FIG. 3, the organic EL elements 2 include a substrate 11, an interlayer insulating layer 12, pixel electrodes (anodes) 13, banks 14, hole injection layers 15, hole transport layers 16, organic light-emitting layers 17, an intermediate layer 18, a second functional layer 19, a counter electrode (cathode) 20, and a sealing layer 21.

The substrate 11, the interlayer insulating layer 12, the intermediate layer 18, the second functional layer 19, the counter electrode 20, and the sealing layer 21 do not correspond one-to-one with each pixel, but are common to a plurality of the organic EL elements 2 in the organic EL display panel 10.

### (1) Substrate

The substrate 11 includes a base 111 that is an insulative material, and a thin film transistor (TFT) layer 112. A drive circuit for each sub-pixel is formed in the TFT layer 112. According to at least one embodiment, the base 111 is a glass substrate, a quartz substrate, a silicon substrate, a metal substrate where the metal is molybdenum sulfide, copper, zinc, aluminum, stainless steel, magnesium, iron, nickel, gold, silver, or the like, a semiconductor substrate where the semiconductor is gallium arsenide or the like, a plastic substrate, or the like.

According to at least one embodiment, a plastic material of the plastic substrate is a thermoplastic resin or a thermosetting resin. Examples of the plastic material include polyethylene, polypropylene, polyamide, polyimide (PI), polycarbonate, acrylic resin, polyethylene terephthalate (PET), polybutylene terephthalate, polyacetal, another fluororesin, a styrene-based, polyolefin-based, polyvinyl chloride-based, polyurethane-based, fluororubber-based, or chlorinated polyethylene-based thermoplastic elastomer, an epoxy resin, an unsaturated polyester, a silicone resin, polyurethane, or the like, or a copolymer, blend, polymer alloy or the like primarily composed of one of the materials listed above, or a stack of two or more of the above.

### (2) Interlayer Insulating Layer

The interlayer insulating layer 12 is disposed on the substrate 11. The interlayer insulating layer 12 is made of a resin material, and planarizes unevenness of an upper surface of the TFT layer 112. According to at least one embodiment, the resin material is a positive type photosensitive material. Examples of such photosensitive material include acrylic resin, polyimide resin, siloxane resin, and phenolic resin. Although not illustrated in the cross-section diagram of FIG. 3, for each sub-pixel a contact hole is formed in the interlayer insulating layer 12.

### (3) Pixel Electrodes

Each of the pixel electrodes 13 includes a metal layer made of a light-reflective metal material, and is disposed on the interlayer insulating layer 12. The pixel electrodes 13 correspond one-to-one with the sub-pixels, and are electrically connected to the TFT layer 112 via the contact holes (not illustrated). According to at least one embodiment, the pixel electrodes 13 function as anodes.

Examples of the light-reflective metal material include silver (Ag), aluminum (Al), aluminum alloy, molybdenum (Mo), silver palladium copper alloy (APC), silver rubidium gold alloy (ARA), molybdenum chromium alloy (MoCr), molybdenum tungsten alloy (MoW), nickel chromium alloy (NiCr), and the like.

According to at least one embodiment, each of the pixel electrodes is a single metal layer. According to at least one embodiment, each of the pixel electrodes is a stack in which a layer made of a metal oxide such as indium tin oxide (ITO) or indium zinc oxide (IZO) is stacked on the metal layer.

### (4) Banks and Pixel Regulation Layers

The banks 14 partition the pixel electrodes 13 corresponding to the sub-pixels above the substrate 11 into columns separated in the X direction (see FIG. 2), and each has a line bank shape extending in the Y direction between the sub-pixel columns CR, CG, CB in the X direction.

An electrically insulative material is used for the banks 14. An example of an electrically insulative material is an insulative organic material (such as acrylic resin, polyimide resin, novolac resin, phenolic resin, or the like).

The banks 14 function as structures for preventing ink of different colors from overflowing and mixing when forming the organic light-emitting layers 17 by an application method.

When using a resin material, a photosensitive material is advantageous from the viewpoint of workability. Photosensitivity may be positive or negative.

According to at least one embodiment, the banks 14 have an organic solvent resistance and heat resistance. In order to suppress overflow of ink, according to at least one embodiment, surfaces of the banks 14 have a defined liquid repellency.

Where the pixel electrodes 13 are not present, a bottom surface of the banks 14 is in contact with the top surface of the interlayer insulating layer 12.

The pixel regulation layers 141 are made of an electrically insulating material and cover end portions in the Y direction (FIG. 2) of the pixel electrodes 13 in each sub-pixel column, separating the pixel electrodes 13 from each other in the Y direction.

Film thickness of the pixel regulation layers 141 is set to be slightly greater than film thickness of the pixel electrodes 13 but less than height of a top surface of the organic light-emitting layers 17. As a result, the organic light-emitting layers 17 in each of the sub-pixel columns CR, CG, CB are not partitioned by the pixel regulation layers 141, and flow of ink is not hindered by the pixel regulation layers 141 when forming the organic light-emitting layers 17. Thus, uniform film thickness is facilitated for each of the light emitting layers 17 in each of the sub-pixel columns.

According to the structure described above, the pixel regulation layers 141 improve electrical insulation between the pixel electrodes 13 in the Y direction while suppressing interruption of the light-emitting layers 17 within the sub-pixel columns CR, CG, CB, and improve electrical insulation between the pixel electrodes 13 and the counter electrode 20.

Examples of an electrically insulating material used for the pixel regulation layers 141 include an organic material used as the material of the banks 14, an inorganic material, or the like. According to at least one embodiment, surfaces of the pixel regulation layers 141 are lyophilic with respect to the ink used in forming the organic light-emitting layers 17, in order to facilitate ink spread.

### (5) Hole Injection Layers

The hole injection layers 15 are disposed on the pixel electrodes 13 in the openings 14a for the purpose of promoting injection of holes from the pixel electrodes 13 to the organic light-emitting layers 17. The hole injection layers 15 are made of an oxide of silver (Ag), molybdenum (Mo), chromium (Cr), vanadium (V), tungsten (W), nickel (Ni), iridium (Ir), or the like, or an electrically conductive polymer material such as poly(3,4-ethylenedioxythiophene) polystyrene sulfonate (PEDOT:PSS). According to at least one embodiment, the hole injection layers 15 are made of a metal oxide and have the functions of assisting in hole formation and stably injecting holes to the organic light-emitting layers 17.

According to at least one embodiment, the hole injection layers 15 are made of an electrically conductive polymer material such as PEDOT:PSS by a wet process such as a printing method.

### (6) Hole Transport Layers

The hole transport layers 16 have a function of transporting holes injected from the hole injection layers 15 to the organic light-emitting layers 17. The hole transport layers 16 are made by a wet process such as a printing method using polyfluorene, a polyfluorene derivative, or a polymer compound such as polyarylamine or a polyarylamine derivative that does not have a hydrophilic group.

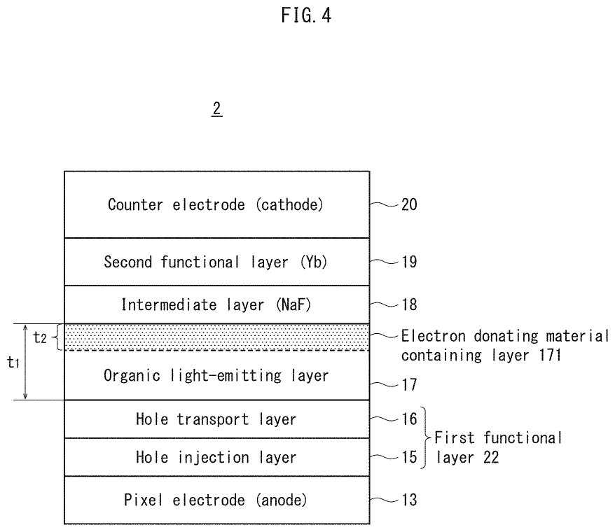

According to at least one embodiment, the hole injection layers 15 and the hole transport layers 16 together constitute first functional layers 22 (see FIG. 4). The first functional layers 22 have a hole injecting property, or a hole transporting property, or both a hole injecting property and a hole transporting property.

### (7) Organic Light-Emitting Layers

The organic light-emitting layers 17 are disposed in the openings 14a, and have a function of emitting light in RGB colors through recombination of holes and electrons. Where a distinction is made between light emission colors, the organic light-emitting layers 17 may be referred to as organic light-emitting layers 17(R), 17(G), 17(B).

The organic light-emitting layers 17 each comprise an organic light-emitting material layer made of an organic light-emitting material, and an electron donating material containing layer 171 made of the organic light-emitting material doped with a metal as an electron donating material (see FIG. 4). According to at least one embodiment, the electron donating material containing layers 171 are formed by diffusing a metal contained in the intermediate layer 18 and/or the second functional layer 19 into the organic light-emitting layers 17. As a result, an energy barrier between the organic light-emitting layers 17 and the second functional layer 19 becomes small, an amount of electrons injected from the counter electrode 20 to the organic light-emitting layers 17 increases, a good carrier balance can be obtained, and luminance efficiency can be improved in the organic light-emitting layers 17. More details of this are provided later.

The organic light-emitting material used in the organic light-emitting layers 17 can be a known material. For example, a fluorescent substance such as an oxinoid compound, a perylene compound, a coumarin compound, an azacoumarin compound, an oxazole compound, an oxadiazole compound, a perinone compound, a pyrrolo-pyrrole compound, a naphthalene compound, an anthracene compound, a fluorene compound, a fluoranthene compound, a tetracene compound, a pyrene compound, a coronene compound, a quinolone compound and azaquinolone compound, a pyrazoline derivative and pyrazolone derivative, a rhodamine compound, a chrysene compound, a phenanthrene compound, a cyclopentadiene compound, a stilbene compound, a diphenylquinone compound, a styryl compound, a butadiene compound, a dicyanomethylene pyran compound, a dicyanomethylene thiopyran compound, a fluorescein compound, a pyrylium compound, thiapyrylium compound, a selenapyrylium compound, a telluropyrylium compound, an aromatic aldadiene compound, an oligophenylene compound, a thioxanthene compound, a cyanine compound, an acridine compound, a metal complex of an 8-hydroxyquinoline compound, a metal complex of a 2-bipyridine compound, a complex of a Schiff base and a group HI metal, a metal complex of oxine, a rare earth metal complex, a phosphorescent metal complex such as tris(2-phenylpyridine) indium, or the like.

### (8) Intermediate Layer

The intermediate layer 18 has a function of preventing movement of water from lower organic layers to the second functional layer 19 while also transporting electrons from the counter electrode 20 to the organic light-emitting layers 17. The intermediate layer 18 is made of sodium fluoride (NaF). By vapor deposition of a material that has a reducing property on an upper layer, NaF has an excellent electron injection property as well as low water permeability for waterproofing.

Further, some of the reduced and dissociated Na atoms diffuse into the organic light-emitting layers 17, increasing carrier density in the organic light-emitting layers 17 and functioning to reduce an energy barrier to the second functional layer 19.

According to at least one embodiment, film thickness of the intermediate layer 18 is from 1 nm to 10 nm.

### (9) Second Functional Layer

The second functional layer 19 is disposed on the intermediate layer 18 and has a function of transporting electrons injected from the counter electrode 20 to the organic light-emitting layers 17.

According to at least one embodiment, the second functional layer 19 is composed of a single layer of ytterbium (Yb), and is made by forming a Yb film on the intermediate layer 18 by a vapor deposition method or a sputtering method.

Yb has a reducing property as well as an excellent electron injection property due to a low work function. Further, Yb is chemically stable compared to alkali metals and alkaline earth metals (hereinafter also referred to as “alkali metals and the like”), and has the excellent characteristics of not easily reacting with impurities such as water as well as not easily deteriorating.

Thus, liquid resistance is further increased in comparison with a conventional organic material doped with an alkali metal or the like, and an effective contact area between Yb and NaF increases, and therefore a reducing action is promoted in NaF by Yb. Dissociated Na further improves electron injection and diffuses into the organic light-emitting layers 17 to form the electron donating material containing layers 171.

According to at least one embodiment, film thickness of the Yb layer is from 0.1 nm to 10 nm. A film thickness of less than 0.1 nm may not obtain a sufficient electron injection property, and a film thickness exceeding 10 nm incurs a risk of causing a problem in light transmission and a decrease in luminance efficiency.

When film thickness of the intermediate layer 18 is small, Yb diffuses into the organic light-emitting material of the organic light-emitting layers 17. Yb is a trivalent positive ion, and diffusion of Yb into the organic light-emitting material is therefore more effective in increasing carrier density in the organic light-emitting layers 17 than in a case where only Na is diffused.

### (10) Counter Electrode

The counter electrode 20 is made of a light-transmissive electrically conductive material and is disposed on the second functional layer 19. The counter electrode 20 functions as an anode.

As the counter electrode 20, a metal thin film or a light-transmissive electrically conductive film such as ITO or IZO can be used. According to at least one embodiment, in order to more effectively obtain an optical resonator structure, a metal thin film made of at least one of aluminum, magnesium, silver, aluminum-lithium alloy, magnesium-silver alloy, or the like is used as the material of the counter electrode 20. In this case, film thickness of the metal thin film is from 5 nm to 30 nm. As a result, the counter electrode 20 is partially light-transmissive and partially light-reflective, and an optical resonator structure is constructed between the pixel electrodes 13 and each reflecting surface of the counter electrode 20, thereby further improving luminance efficiency.

According to at least one embodiment, when the optical resonator structure described above is adopted, a light-transmissive electrically conductive thin film of ITO, IZO, or the like is formed between the second functional layer 19 and the counter electrode 20 to have a desired film thickness, in order to adjust an optical distance between the organic light-emitting layers 17 and the counter electrode 20 to an appropriate length.

Further, according to at least one embodiment, a light-transmissive electrically conductive film of ITO, IZO, or the like is also formed on the counter electrode to adjust chromaticity and viewing angle.

### (11) Sealing Layer

The sealing layer 21 is provided to prevent organic layers such as the hole transport layers 16, the organic light-emitting layers 17 and the second functional layer 19 from deteriorating due to exposure to moisture and air.

The sealing layer 21 is formed by using, for example, a light-transmissive material such as silicon nitride (SiN), silicon oxynitride (SiON), or the like.

### (12) Other Structure

Although not illustrated in FIG. 3, according to at least one embodiment an antiglare polarizing plate or an upper substrate is bonded onto the sealing layer 21 by a light-transmissive adhesive. Further, according to at least one embodiment, a color filter for correcting chromaticity of light emitted by each of the organic EL elements 2 is attached. As a result, the hole transport layers 16, the organic light-emitting layers 17, the second functional layer 19, and the like can be further protected from external moisture, air, and the like.

### 3. Appropriate Carrier Movement Between Light-Emitting Layer and Adjacent Layer

The following describes a method for optimizing carrier movement in a light-emitting layer in an organic EL element, with reference to the drawings.

### (1) Stacked Structure in Main Part of Organic EL Element

FIG. 4 is a schematic diagram illustrating a stacked structure of a main part of an organic EL element according to at least one embodiment (from anode to cathode: hereinafter also referred to as a “light emission section”).

As illustrated, the light emission section is a stack including the pixel electrodes 13, the first functional layers 22 (the hole injection layers 15, the hole transport layers 16), the organic light-emitting layers 17, the intermediate layer 18, the second functional layer 19, and the counter electrode 20.

The electron donating material containing layers 171 are formed on sides of the organic light-emitting layers 17 facing the counter electrode 20 (in this example, an interface with the intermediate layer 18).

The electron donating material containing layers 171 are formed by doping the organic light-emitting material that is a base of the organic light-emitting layers 17 with electron donating material. According to at least one embodiment, at least one metal dopant is selected from a group consisting of alkali metals, alkaline earth metals, and rare earth metals.

According to at least one embodiment, Na included in NaF that is a material of the intermediate layer 18 and Yb from the second functional layer 19 are diffused into the organic light-emitting material of the organic light-emitting layers 17 to form the electron donating material containing layers 171. However, when film thickness of the intermediate layer 18 is thick, Yb from the second functional layer 19 might not permeate into the organic light-emitting layers 17, but at least Na from the intermediate layer 18 in direct contact with the organic light-emitting layers 17 permeates and diffuses into the organic light-emitting layers 17 to form the electron donating material containing layers 171.

The dopant as the electron donating material is diffused and distributed in a film thickness direction of the organic light-emitting material layers made of the organic light-emitting material having a film thickness of t1, to form the electron donating material containing layers 171 having a film thickness of t2, where t2<t1. However, an interface in the organic light-emitting layers 17 between the electron donating material containing layers 171 and portions other than the electron donating material containing layers 171 is not always clear. FIG. 4 is just a schematic representation.

Doping with the metal of the electron donating material increases carrier density of the organic light-emitting layers 17 and reduces an energy barrier with the second functional layer 19.

In each of the organic light-emitting layers 17, it is preferable that a location where holes and electrons recombine to emit light (a location where density of generated excitons is high) is as close as possible to a pixel electrode 13 side interface of the organic light-emitting layer 17 (hereinafter also referred to as an “anode side interface”). The electron donating material containing layers 171 are formed by diffusion of an alkali metal or the like from the intermediate layer 18, and therefore a concentration near the counter electrode 20 side interface of each of the organic light-emitting layers 17 (hereinafter also referred to as a “cathode side interface”) is highest, and decreases towards the anode side interface.

By making a light emission center as close to the anode side interface as possible, a reduction in an amount of excitons that contribute to light emission due to the energy of excitons generated by recombination of holes and electrons being absorbed by the dopant is prevented as much as possible.

Thus, a concentration of the electron donating material dopant in the organic light-emitting layers 17 is preferably higher at the cathode side interface than at the anode side interface, and a density of excitons generated in the organic light-emitting layers 17 is preferably higher at the anode side interface than at the cathode side interface.

Thus, film thicknesses of the organic light-emitting layers 17 and organic materials having required electron mobilities, film thickness of the intermediate layer 18 (an amount of Na that can be reduced by the second functional layer 19 and diffused into the organic light-emitting materials), and the like are determined in advance by experiments or the like.

According to at least one embodiment, the intermediate layer 18 is made of NaF. According to at least one embodiment, the intermediate layer 18 is made of a fluoride of a metal selected from other alkali metals of alkaline earth metals. The intermediate layer 18 made of a fluoride of a metal selected from other alkali metals or alkaline earth metals also has a water blocking property and when reduced by Yb, the metal exhibits an electron injection property. However, if blocking of impurities such as water is not particularly emphasized, and only diffusion of metal into the electron donating material is focused on, the material of the intermediate layer 18 is not particularly limited to a fluoride, and may be a compound of a metal and another element.

Yb of the second functional layer 19 has a reducing property, and therefore NaF of the intermediate layer 18 is partially reduced and dissociated, the dissociated Na permeates and diffuses mainly into the intermediate layer 18 side of the organic light-emitting layers 17 as an electron donating material, forming the electron donating material containing layers 171.

According to at least one embodiment, a metal of the second functional layer 19 is another rare earth metal, not Yb. The low work function, reducing property, and chemical stability of Yb are properties common to other rare earth metals. However, compared to other rare earth metals, Yb has excellent characteristics such as a low melting point and high light transmission.

By forming the electron donating material containing layers 171 in the organic light-emitting layers 17 as described above, carrier balance in the organic light-emitting layers 17 when a voltage is applied to the pixel electrodes 13 and the counter electrode 20 is improved, drive voltage can be lowered, and luminance efficiency is improved.

### (2) Carrier Balance Improvement

FIG. 5 is a schematic diagram illustrating a state in which energy levels of a hole transport layer, a light-emitting layer, and an electron transport layer are appropriately balanced in the organic EL element according to at least one embodiment.

As illustrated, in a state where a voltage is applied between a pixel electrode (anode) and the counter electrode (cathode), holes are supplied to a highest occupied molecular orbital (HOMO) of a light-emitting layer from the pixel electrode via a hole transport layer and electrons are supplied to a lowest unoccupied molecular orbital (LUMO) of the light-emitting layer from the counter electrode via the electron transport layer. Holes supplied from the hole transport layer side and electrons supplied from the electron transport layer side recombine in the light-emitting layer to generate an excited state and emit light.

In this recombination, if a good carrier balance is maintained such that electrons and holes injected into the light-emitting layer are quantitatively balanced, the electrons and holes are recombined without excess or shortage. In such a case, all holes and electrons can contribute to light emission without generation of residual holes or electrons, and luminance efficiency of the organic EL element can be optimized.

In contrast, if energy levels of a hole transport layer, a light-emitting layer, and an electron transport layer are not appropriate, carrier transfer to the light-emitting layer does not occur appropriately.

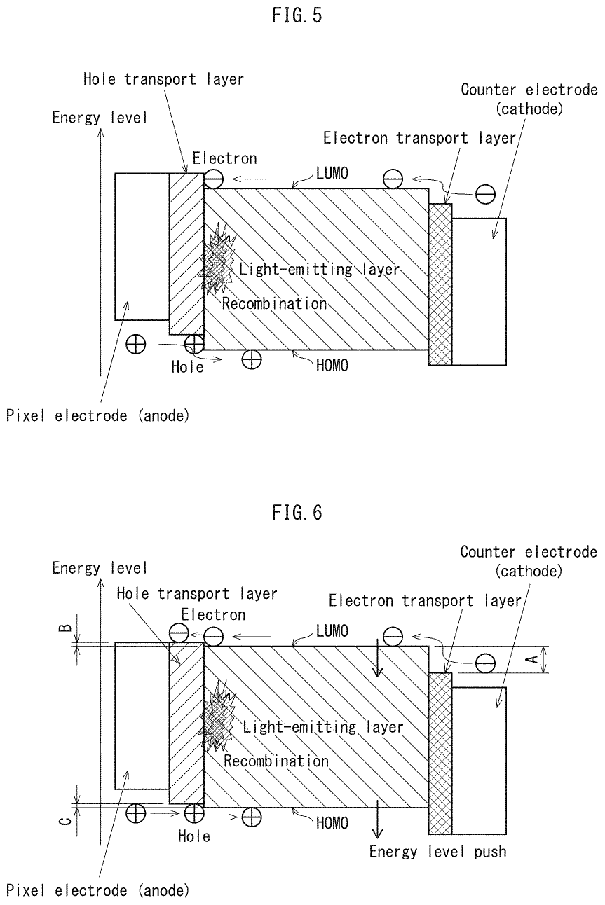

FIG. 6 is a schematic diagram illustrating a state in which energy levels of a hole transport layer, a light-emitting layer, and an electron transport layer are not appropriately balanced in an organic EL element. As illustrated, a position of an energy level of the light-emitting layer relative to energy levels of the hole transport layer and the electron transport layer is above that of the energy level illustrated in FIG. 5.

Thus, a position of the LUMO level of the light-emitting layer relative to the energy level of the electron transport layer is shifted upwards, and a difference A between the energy levels is increased relative to the state illustrated in FIG. 5. As a result, when a voltage is applied between the pixel electrode and the counter electrode, the energy barrier to electron supply from the counter electrode to the light-emitting layer via the electron transport layer is increased, and an amount of electrons flowing into the light-emitting layer is reduced.

Further, a difference B between the energy level of the hole transport layer and the LUMO level of the light-emitting layer is smaller than that illustrated in FIG. 5. As a result, an energy barrier against electron outflow from the LUMO of the light-emitting layer to the hole transport layer is reduced, and an amount of electrons flowing out from the light-emitting layer to the hole transport layer is increased. Further, an amount of holes flowing from the hole transport layer to the light-emitting layer increases.

Thus, a position of the HOMO level of the light-emitting layer relative to the energy level of the hole transport layer is shifted upwards, and a difference C between the energy levels is decreased relative to the state illustrated in FIG. 5. As a result, when a voltage is applied between the pixel electrode and the counter electrode, an amount of holes flowing from the pixel electrode into the HOMO of the light-emitting layer via the hole transport layer is increased.

As a result, a quantitative imbalance occurs between electrons and holes in the light-emitting layer, and an amount of electrons that recombine with holes in the light-emitting layer to contribute to light emission becomes smaller than an amount of holes supplied to the light-emitting layer, causing a problem of a reduction in luminance efficiency of the organic EL element.

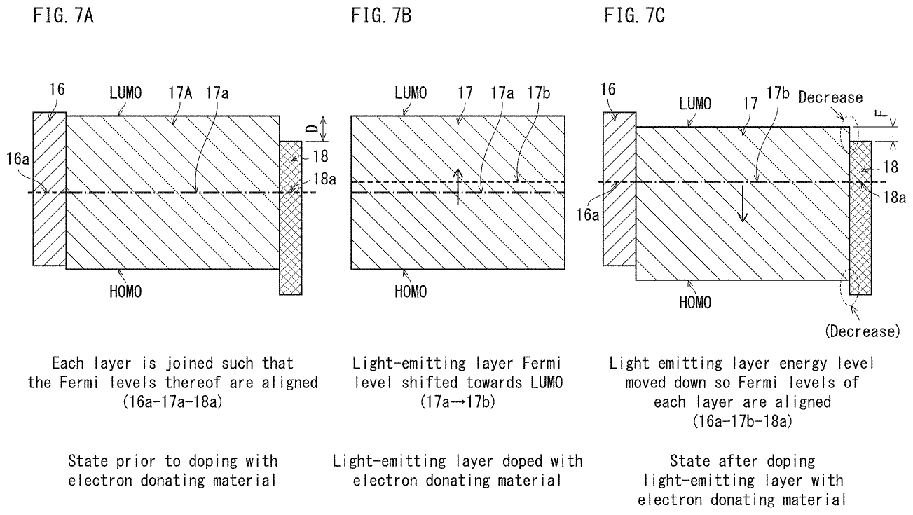

FIG. 7A, 7B, 7C are schematic diagrams for explaining an improvement in energy levels of the hole transport layers 16, the organic light-emitting levels 17, and the intermediate layer 18 in the organic EL elements 2. FIG. 7A illustrates energy levels of each layer before an organic light-emitting layer 17 is doped with an electron donating material, FIG. 7B illustrates a change in Fermi level when the organic light-emitting layer 17 is doped with an electron donating material, and FIG. 7C illustrates energy levels of each layer when the organic light-emitting layer 17 is doped with an electron donating material.

As illustrated in FIG. 7A, energy levels of the hole transport layers 16, the organic light-emitting layers 17, and the intermediate layer 18 are positioned such that Fermi levels 16a, 17a, 18a of each layer match. In a case in which the organic light-emitting layers 17 of the organic EL elements 2 do not contain an electron donating material (FIG. 7A), a difference D between an energy level of the intermediate layer 18 and the LUMO level of the light-emitting layers 17 is relatively large, and a difference E between an energy level of the hole transport layers 16 and the LUMO levels of the organic light-emitting layers 17 is relatively small. As a result, as in the case illustrated in FIG. 6, an amount of electrons that recombine with holes in the organic light-emitting layers 17 to contribute to light emission is smaller relative to an amount of holes supplied into the organic light-emitting layers 17

Here, the Fermi level of the organic light-emitting layers 17 shifts from 17a to 17b towards the LUMO side due to addition of an electron donating material to the organic light-emitting layers 17 (FIG. 7B).

Then, as illustrated in FIG. 7C, energy levels of each layer are rearranged such that the Fermi levels 16a, 17b, 18a of each layer match. When compared to FIG. 7A, a difference F between the energy level of the intermediate layer 18 and the LUMO level of the organic light-emitting layers 17 is decreased.

Thus, an amount of electrons flowing from the intermediate layer 18 to the organic light-emitting layers 17 increases. As a result, an amount of electrons that recombine with holes in the light-emitting layer to contribute to light emission increases, and luminance efficiency of the organic EL elements 2 increases.

Accordingly, by shifting the Fermi level of at least a portion of each of the organic light-emitting layers 17 near a cathode-side interface towards the LUMO level thereof, an amount of electrons in the organic light-emitting layers 17 and contributing to recombination with holes can be balanced with an amount of holes supplied to the organic light-emitting layers 17 from the hole transport layers 16, such that electrons and holes can be recombined without excess or deficiency, to contribute to light emission and improve luminance efficiency of organic EL elements.

That is, the HOMO levels and the LUMO levels of the organic light-emitting layers 17 are controlled by the inclusion of the electron donating material in the organic light-emitting material, and the injection energy barriers to the intermediate layers 18 adjacent to the organic light-emitting layers 17 are optimized. As a result, quantitative balance (carrier balance) of electrons and holes injected in to the organic light-emitting layers 17 can be optimized, improving luminance efficiency.

### (3) Relationship Between Organic Light-Emitting Layer Energy Level Shift Amount, Luminance Efficiency, and Applied Voltage

Energy level shift amount, luminance efficiency, and applied voltage with respect to the organic light-emitting layers 17 in the organic EL elements 2 are described with reference to the drawings.

A calculation was run using a device simulator in which energy levels indicating HOMO level and LUMO level of the organic light-emitting layers 17 were changed. In the device simulator, the HOMO level and the LUMO level of the organic light-emitting layer illustrated in FIG. 5 were changed, and a current property and an efficiency property were evaluated.

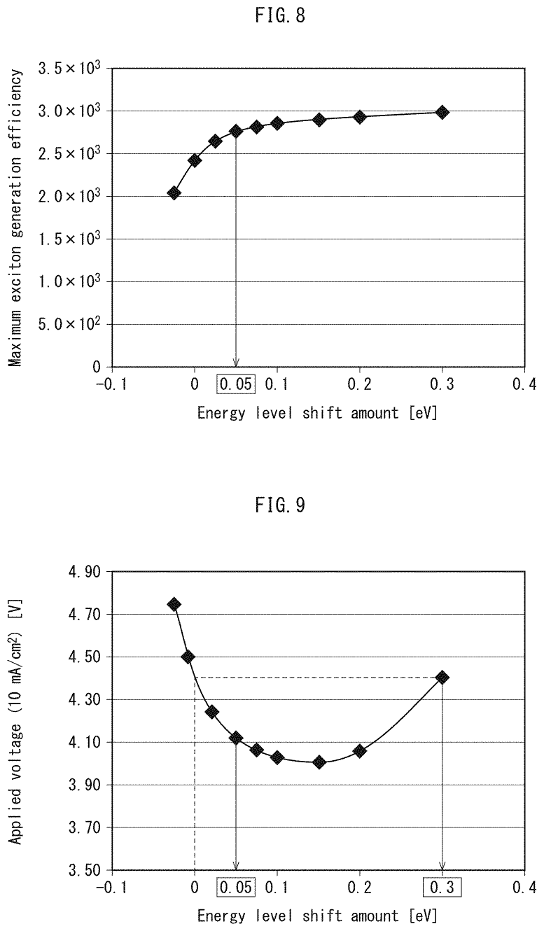

FIG. 8 is a diagram of simulation results illustrating a relationship between shift amounts of energy levels of light-emitting layers and maximum exciton generation efficiency, in the organic EL elements 2. FIG. 9 is a diagram of simulation results illustrating a relationship between shift amounts of energy levels of light-emitting layers and a required applied voltage per unit of current (applied voltage for current flow in 10 mA/cm).

In FIG. 8 and FIG. 9, the shift amounts of energy levels of light-emitting layers are relative to a reference value of 0 eV of a state in which the organic light-emitting layers 17 do not contain the electron donating material (a state in which only the organic light-emitting material layer 170 is formed).

As illustrated in FIG. 8, exciton generation efficiency, which is an index of luminance efficiency, is increased by shifting the energy levels of the organic light-emitting layers 17 in a positive direction from the reference value (0 eV). By shifting about 0.05 eV from the reference value, an amount of loss from a maximum value of exciton generation efficiency (at about 0.3 eV) is approximately halved, and by shifting about 0.1 eV from the reference value, exciton generation efficiency is almost saturated.

On the other hand, as illustrated in FIG. 9, applied voltage for a unit of current (10 mA/cm²) to flow is gradually reduced by shifting the energy level of the organic light-emitting layers 17 in the positive direction from the reference value (0 eV), and a minimum value is indicated when the shift amount is about 0.15 eV from the reference value. Further, by shifting the energy level of the organic light-emitting layers 17 further in the positive direction, the applied voltage gradually increases, and an applied voltage value that does not exceed the reference value is indicated at about 0.3 eV.

From these results it can be seen that it is possible to improve luminance efficiency and reduce a drive voltage of the organic EL elements 2 by shifting the energy level of the organic light-emitting layers 17 in the positive direction in a range from 0.05 eV to 0.3 eV from the reference value of 0 eV of a state in which the electron donating material is not included.

### (4) Relationship Between Energy Level Shift Amount and Carrier Density of Organic Light-Emitting Layers 17

A dopant concentration was calculated of the electron donating material necessary to shift the energy level of the organic light-emitting layers 17 in the positive direction in the range from 0.05 eV to 0.3 eV from the reference value of a state without the electron donating material.

In general, where Ef is energy level (Fermi level) when an n-type dopant is added to an intrinsic semiconductor, and Ei is the Fermi level of the intrinsic semiconductor, an energy shift amount (Ef−Ei) can be calculated by the following expression.

Ef−Ei=k·T·ln(Nd/ni)

Here, Ef represents Fermi level, Ei represents intrinsic semiconductor Fermi level, k represents Boltzmann constant, T represents absolute temperature, Nd represents n-type carrier density (cm⁻³), and ni represents intrinsic semiconductor carrier density (cm⁻³).

Using the expression above, the relationship between shift amounts of energy levels of organic light-emitting layers (Ef−Ei) and carrier density of n-type impurities can be calculated.

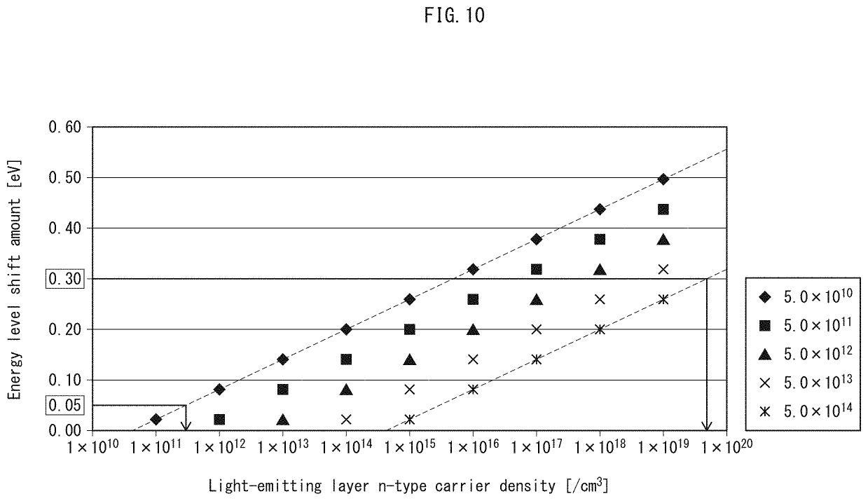

FIG. 10 is a diagram of calculation results illustrating the relationship between shift amounts of energy levels of light-emitting layers and n-type carrier density of light-emitting layers, for application to the organic EL elements 2.

In this calculation, carrier density of the organic light-emitting layers 17 without the electron donating material (organic light-emitting material layer 170) was used instead of the intrinsic semiconductor carrier density ni. More specifically, carrier density of the organic light-emitting layers 17 without the electron donating material was calculated assuming realistic values determined by the inventor from 5×10¹⁰/cm³ to 5×10¹⁴/cm³.

According to FIG. 10, when an energy level of the organic light-emitting layers 17 is shifted in the positive direction in the range from 0.05 eV to 0.3 eV, the n-type carrier density of the organic light-emitting layers 17 is from 3.5×10¹¹/cm³ to 5.5×10¹⁹/cm. According to at least one embodiment, the range is from 10¹²/cm³ to 10¹⁹/cm³.

When the electron donating material is composed of an alkali metal that becomes a monovalent ion, the n-type carrier density Nd becomes a density at which the electron donating material is mixed. When the electron donating material becomes a multivalent ion, a density at which the electron donating material is mixed is converted from the n-type carrier density Nd according to valence. For example, when the electron donating material is composed of an alkaline earth metal that becomes a divalent ion, the density at which the electron donating material is mixed is ½ of the n-type carrier density Nd.

Further, using the results of FIG. 10, it is possible to obtain a relationship in the organic EL elements 2 between the shift amounts of the energy levels of light-emitting layers and a rate of change of n-type carrier density accompanying addition of the electron donating material of light-emitting layers.

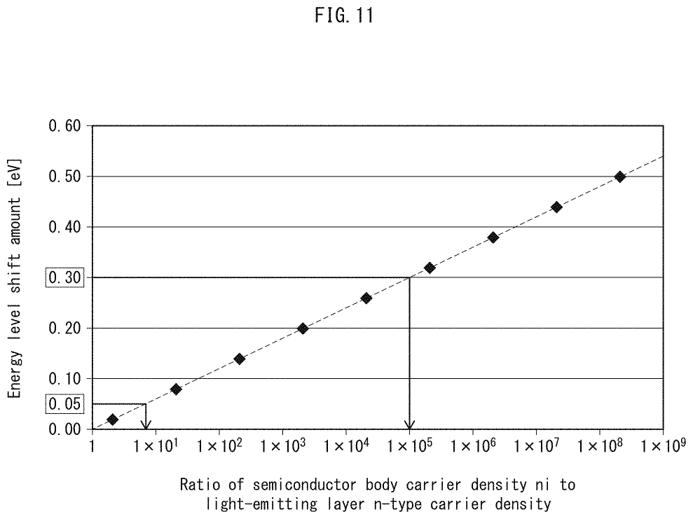

FIG. 11 is a diagram of calculation results illustrating the relationship between the shift amounts of the energy levels of light-emitting layers and a ratio of n-type carrier density of light-emitting layers to carrier density ni of intrinsic semiconductors for application to the organic EL elements 2. As illustrated in FIG. 11, in order to shift the energy levels of the organic light-emitting layers 17 in the positive direction by a range from 0.05 eV to 0.3 eV, the organic light-emitting layers 17 from a state of not including electron donating material require addition of electron donating material with a carrier density from 7 to 1×10⁵ times carrier density of the organic light-emitting material. According to at least one embodiment, the ratio is from 10 to 1-10⁵ times.

### 4. Experimental Results of Luminance Efficiency and Applied Voltage Using Organic EL Elements 2

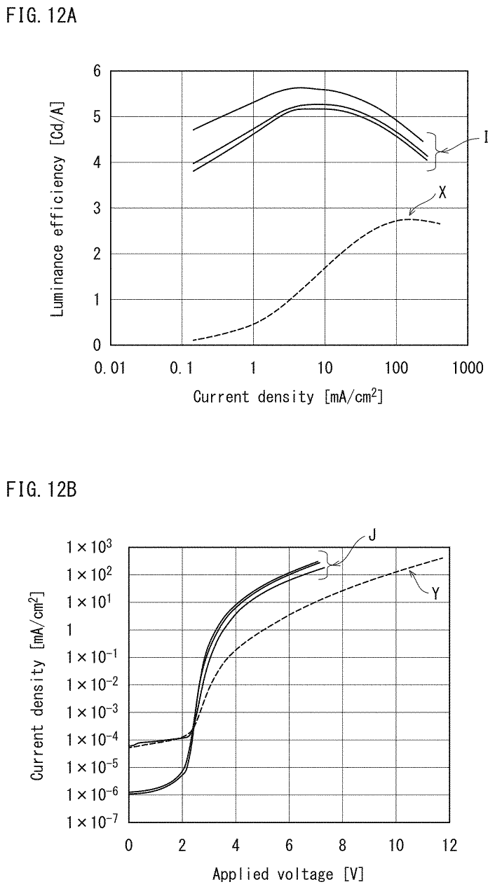

Luminance efficiency and applied voltage were measured using samples of the organic EL elements 2. FIG. 12A is a diagram of experimental results illustrating a relationship between current density and maximum exciton efficiency of light-emitting layers in the organic EL elements 2, and FIG. 12B is a diagram of experimental results illustrating a relationship between applied voltage and current density in the organic EL elements 2.

In each of the samples of the organic EL elements 2, an electron donating material is added to the organic light-emitting layer 17 to shift the energy level of the organic light-emitting layer 17 in the positive direction in a range from 0.05 eV to 0.3 eV. As a reference example, a sample in which the light-emitting layer contains no electron donating material was used.

As illustrated in FIG. 12A, when comparing experimental results I (solid lines) of luminance efficiency of samples of the organic EL elements 2 to an experimental result X (dashed line) of luminance efficiency of a sample of a reference example, it can be seen that luminance efficiency is higher in terms of current density.

Further, as illustrated in FIG. 12B, when comparing experimental results J (solid lines) of current density of samples of the organic EL elements 2 to an experimental result Y (dashed line) of current density of a sample of a reference example, it can be seen that current density is larger at a range of values of applied voltage.

From the above results, when comparing the samples of the organic EL elements 2 in which the energy levels of the organic light-emitting layers 17 were positively shifted in the range from 0.05 eV to 0.3 eV from the reference value to a sample in which the light-emitting layer does not contain the electron donating material, it can be seen that luminance efficiency is improved and drive voltage can be reduced.

### 5. Organic EL Element Manufacturing Method

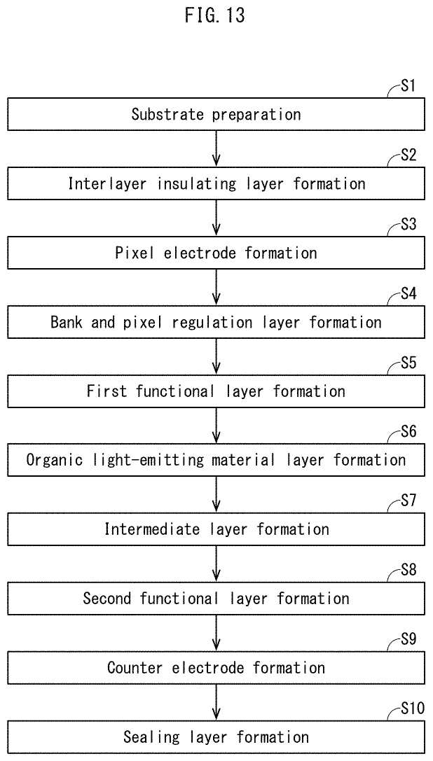

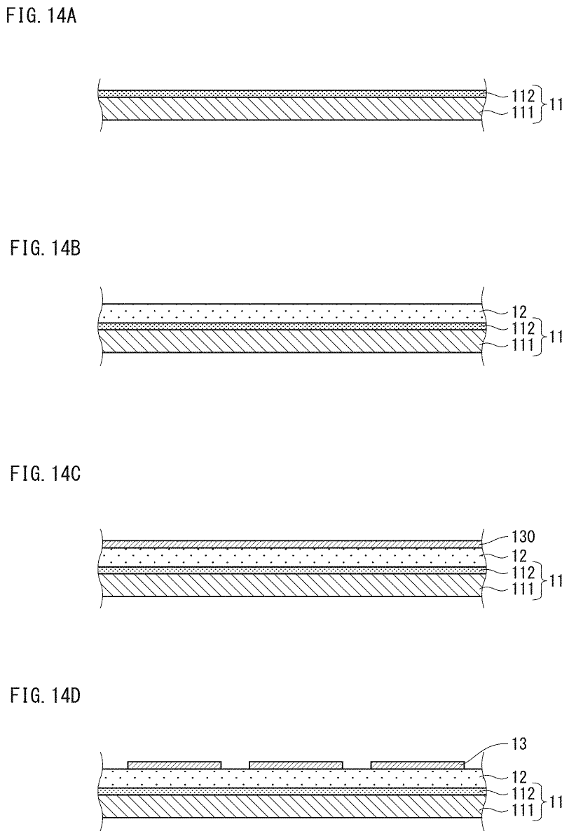

A method of manufacturing the organic EL elements 2 according to at least one embodiment is described below, with reference to FIG. 13 to FIG. 17D. FIG. 13 is a flowchart illustrating a process of manufacturing the organic EL elements 2, and FIG. 14A to FIG. 17D are cross-section diagrams schematically illustrating the process of manufacturing the organic EL elements 2.

### (1) Substrate Preparation

First, as illustrated in FIG. 14A, the TFT layer 112 is formed on the base 111 to prepare the substrate 11 (step S1 in FIG. 13). The TFT layer 112 can be formed by a known TFT manufacturing method.

### (2) Interlayer Insulating Layer Formation

Next, as illustrated in FIG. 14B, the interlayer insulating layer 12 is formed on the substrate 11 (step S2 in FIG. 13).

Specifically, photosensitive resin material having a defined fluidity is applied across the top surface of the substrate 11 by, for example, a die coating method, so as to fill irregularities in the top surface of the substrate 11 due to the TFT layer 112. Thus, the top surface of the interlayer insulating layer 12 is planarized to conform to the top surface of the base 111.

Further, a dry etching method is applied to positions of the interlayer insulating layer 12 above TFT elements, for example source electrodes, to form contact holes (not illustrated). The contact holes are formed by patterning or the like such that surfaces of the source electrodes of the TFT elements are exposed at bottoms of the contact holes.

Next, connecting electrode layers are formed along inner walls of the contact holes. Top portions of the connecting electrode layers are disposed on the interlayer insulating layer 12. According to at least one embodiment, the connecting electrode layers are formed by a sputtering method to form a metal film, followed by patterning by using a photolithography method or wet etching method.

### (3) Pixel Electrodes Formation

Next, as illustrated in FIG. 14C, a pixel electrode material layer 130 is formed on the interlayer insulating layer 12. According to at least one embodiment, the pixel electrode material layer 130 is formed using a vacuum deposition method, a sputtering method, or the like.

Then, as illustrated in FIG. 14D, the pixel electrode material layer 130 is patterned by etching to form the pixel electrodes 13 corresponding one-to-one with sub-pixels (step S3 in FIG. 13).

### (4) Banks and Pixel Regulation Layers Formation

Next, the banks 14 and the pixel regulation layers 141 are formed (step S4 in FIG. 13).

According to at least one embodiment, the pixel regulation layers 141 and the banks 14 are formed in separate processes.

### (4-1) Pixel Regulation Layers Formation

First, in order to partition the pixel electrode columns in the Y direction (FIG. 2) into sub-pixels, the pixel regulation layers 141 are formed extending in the X direction.

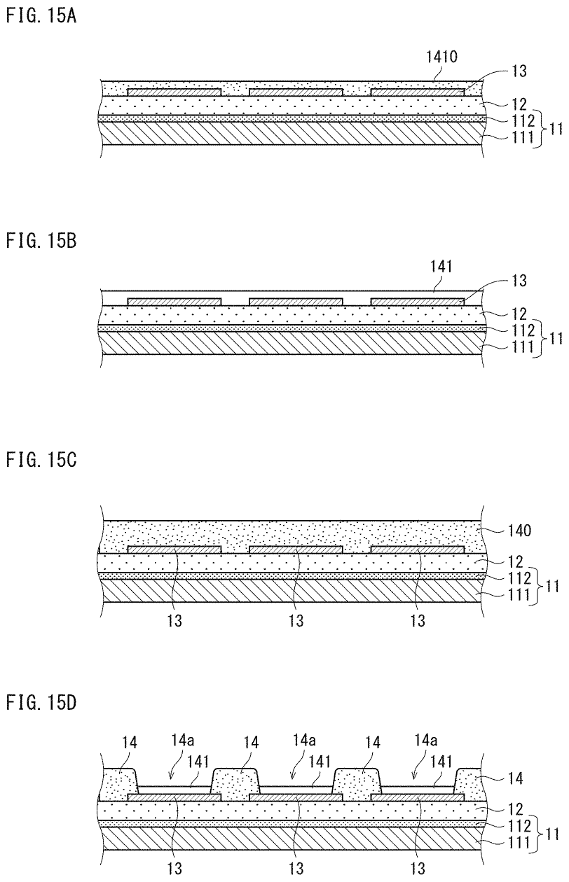

As illustrated in FIG. 15A, a photosensitive resin material that is to be a material of the pixel regulation layers 141 is uniformly applied on the interlayer insulating layer 12 and the pixel electrodes 13 thereon, to form the pixel regulation layer material layer 1410. An amount of resin material applied at this time is determined in advance such that a target film thickness of the pixel regulation layers 141 is obtained after drying.

As a specific example of an application method, according to at least one embodiment, a wet method such as a die coating method, a slit coating method, a spin coating method, or the like is used. After application, according to at least one embodiment, vacuum drying and low temperature heat drying (prebaking) at about 60° C. to 120° C. are performed to remove an unnecessary solvent and fix the pixel regulation layer material layer 1410 to the interlayer insulating layer 12.

A photolithography method is then used to pattern the pixel regulation layer material layer 1410.

For example, according to at least one embodiment, the pixel regulation layer material layer 1410 has positive photosensitivity, portions that are to remain as the pixel regulation layers 141 are shielded from light, and portions to be removed are exposed to light through a light-transmissive photomask (not illustrated).

Next, the pixel regulation layers 141 can be formed by developing and removing the exposed positions of the pixel regulation layer material layer 1410. As a specific developing method, an example is to immerse the substrate 11 in a developing solution such as an organic solvent or alkaline solution that dissolves portions of the pixel regulation layer material layer 1410 that have been exposed to light, then immerse the substrate 11 in a rinsing liquid such as pure water to wash the substrate 11.

Then, by baking (post-baking) at a defined temperature, the pixel regulation layers 141 extending in the X direction can be formed on the interlayer insulating layer 12 (FIG. 15B).

### (4-2) Bank Formation

Next, the banks 14 extending in the Y direction are formed in a similar way to the pixel regulation layers 141.

That is, a bank resin material is applied on the interlayer insulating layer 12, the pixel electrodes 13, and the pixel regulation layers 141 by a die coating method or the like to form a bank material layer 140 (FIG. 15C). An amount of resin material applied at this time is determined in advance such that a target height of the banks 14 is obtained after drying.

Then, after using a photolithography method on the bank material layer 140 to pattern the banks 14 extending in the Y direction, the banks 14 are formed by baking at a defined temperature (FIG. 15D).

The above description is of the material layers of the pixel regulation layers 141 and the banks 14 being formed by wet processes and patterned, but according to at least one embodiment one or both of the material layers are formed by a dry process, and a photolithography method and an etching method is used for patterning.

### (5) First Functional Layer Formation

The formation of the first functional layers includes formation of the hole injection layers 15 and formation of the hole transport layers 16 (step S5 in FIG. 13).

First, the hole injection layers 15 are formed by ejecting an ink containing an electrically conductive polymer material such as poly(3,4-ethylenedioxythiophene) polystyrene sulfonate (PEDOT:PSS) from nozzles 3011 of an application head 301 of a printing device 301 into the openings 14a, volatilizing the solvent and/or baking.

The hole transport layers 16 are formed by applying an ink containing a material of the hole transport layers 16 onto the hole injection layers 15 then volatilizing the solvent and/or baking.

According to at least one embodiment, a high molecular weight compound that does not have a hydrophilic group, such as polyfluorene, a polyfluorene derivative, polyarylamine, a polyarylamine derivative, or the like is used as the material of the hole transport layers 16. The application method is the same as that used for the hole injection layers 15.

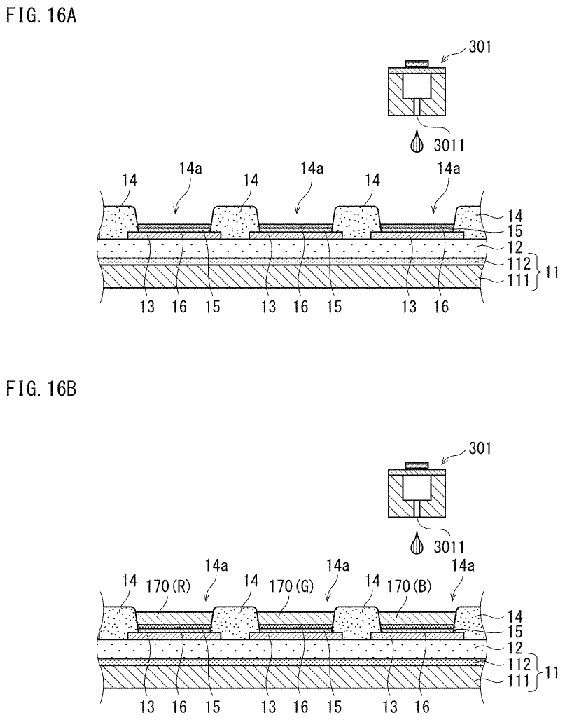

FIG. 16A illustrates a schematic cross-section diagram of the organic EL display panel 10 when the hole transport layers 16 are formed after forming the hole injection layers 15.

### (6) Organic Light-Emitting Material Layers Formation

Next, organic light-emitting material layers 170(R), 170(G), 170(B) (hereinafter, where light emission colors are not distinguished, these layers are referred to as “organic light-emitting material layers 170”) are formed on the hole transport layers 16 as precursors of the organic light-emitting layers 17 (step S6 in FIG. 13).

More specifically, as illustrated in FIG. 16B, inks containing organic light-emitting materials that are materials of organic light-emitting layers of different colors are sequentially ejected from the nozzles 3011 of the application head 301 of the printing device onto the hole transport layers 16 in the openings 14a. After application of ink, the substrate 11 is conveyed into a vacuum drying chamber and heated in a vacuum environment to evaporate organic solvent in the ink. In this way, the organic light-emitting material layers 170 are formed.

### (7) Intermediate Layer Formation

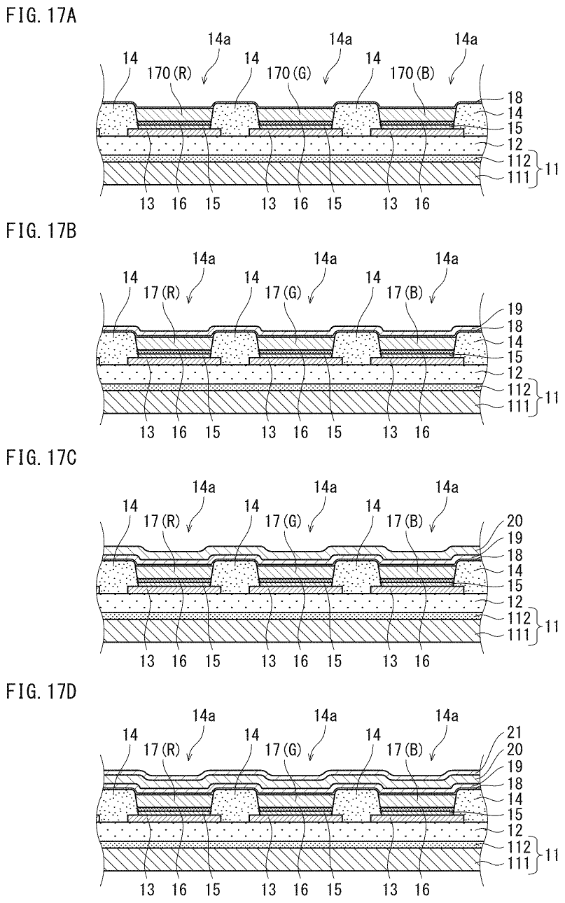

Next, as illustrated in FIG. 17A, the intermediate layer 18 is formed on the organic light-emitting material layers 170 and the banks 14 by a vacuum deposition method or the like to have a film thickness of 4 nm, for example (step S7 in FIG. 13).

As described above, the intermediate layer 18 is composed of NaF, and prevents impurities existing in or on the organic light-emitting material layers 170, the hole transport layers 16, the hole injection layers 15, and the banks 14 from entering the second functional layer 19 and the counter electrode 20, and Na reduced and dissociated by Yb of the second functional layer 19 functions as the electron donating material and diffuses into the organic light-emitting material layers 170.

### (8) Second Functional Layer Formation

Subsequently, as illustrated in FIG. 17B, the second functional layer 19 is formed on the intermediate layer 18 by vacuum deposition or the like to have a film thickness from 0.1 nm to 1 nm (step S8 in FIG. 13). According to at least one embodiment, the second functional layer 19 has a film thickness of 1 nm.

As described above, the second functional layer 19 is composed of Yb, and reduces NaF in the intermediate layer 18 into Na and F.

Film thicknesses of the intermediate layer 18 and the second functional layer 19 are thin, as described above, and Na from the intermediate layer 18 and Yb from the second functional layer 19 diffuse in the film thickness direction into the organic light-emitting material layers 170 during the manufacturing process, such that at least the Na mixes in the organic light-emitting material to form the electron donating material containing layers 171 and finally the organic light-emitting layers 17.

The doping amount of the metal used as the electron donating material can be controlled by the film thickness of the intermediate layer 18, and the film thickness of the intermediate layer 18 is determined in advance by experiments or the like, such that at least a carrier density at the cathode-side interface of the organic light-emitting layers 17 where the dopant concentration is highest is in an optimum range determined by the simulations described above (range from 10²/cm to 10¹⁹/cm³).

### (9) Counter Electrode Formation

Next, the counter electrode 20 is formed on the second functional layer 19 (step S9 in FIG. 13).

The counter electrode 20 is formed by using a sputtering method or vacuum deposition method to form a thin film of silver, aluminum, or the like on the second functional layer 19 (FIG. 17C).

### (10) Sealing Layer Formation

Next, as illustrated in FIG. 17D, the sealing layer 21 is formed on the counter electrode 20 (step S10 in FIG. 13). The sealing layer 21 is formed by forming a film of SiON, SiN, or the like by a sputtering method, a chemical vapor deposition (CVD) method, or the like.

The organic EL display panel 10 illustrated in FIG. 3 is manufactured as described above. The above manufacturing method is simply an illustrative example, and can be appropriately altered to purpose.

### <<Modifications>>

Although the organic EL elements 2 and the like are described above according to various embodiments, the present disclosure is not limited to the embodiments described above except in terms of essential characterizing features. Various modifications of the embodiments conceivable by a person having ordinary skill in the art, and any embodiment of a combination of elements and functions of the embodiments that do not depart from the spirit of the invention are also included in the present disclosure. The following describes modifications of the organic EL elements and the organic EL display panel as examples of such embodiments.

(1) According to the organic EL element 2 according to at least one embodiment, after forming organic light-emitting material layers made of organic light-emitting materials on the first functional layers, the intermediate layer 18 including a compound of a metal (first metal) selected from a group consisting of alkali metals and alkaline earth metals and another element is formed on the organic light-emitting material layers, and the second functional layer 19 including a rare earth metal (second metal) having a reducing property for breaking a bond between the first metal and the other element in the compound of the first metal is formed on the intermediate layer 18, and therefore at least the first metal out of the first metal and the second metal is diffused into the organic light-emitting layers 17 as the electron donating material dopant.

However, the doping method for forming the electron donating material containing layers 171 by mixing the first metal and/or the second metal in organic light-emitting layer 17 is not limited to the above configuration. For example, after forming organic light-emitting material layers made of organic light-emitting material on the first functional layer, the organic light-emitting material layers may be doped with a metal selected from a group consisting of alkali metals, alkaline earth metals, and rare earth metals (hereinafter also referred to as an “electron donating metal”) by, for example, a method such as ion injection so that carrier density is in a range from 10¹²/cm³ to 10¹⁹/cm³.

Alternatively, organic light-emitting material layers 170 having a film thickness of t1-t2 made of only organic light-emitting material may be formed on the first functional layers, and subsequently organic light-emitting layers made of the organic light-emitting material doped with the electron donating metal to have a carrier density from 10¹²/cm³ to 10¹⁹/cm³ may be formed by co-deposition.

Alternatively, doping may be performed by forming organic light-emitting layers by applying inks containing a compound of organic light-emitting materials and the electron donating metal.

### (2) Intermediate Layer and Second Functional Layer Modifications

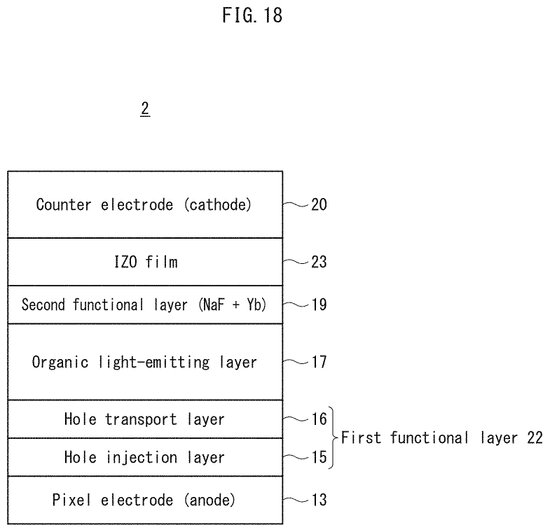

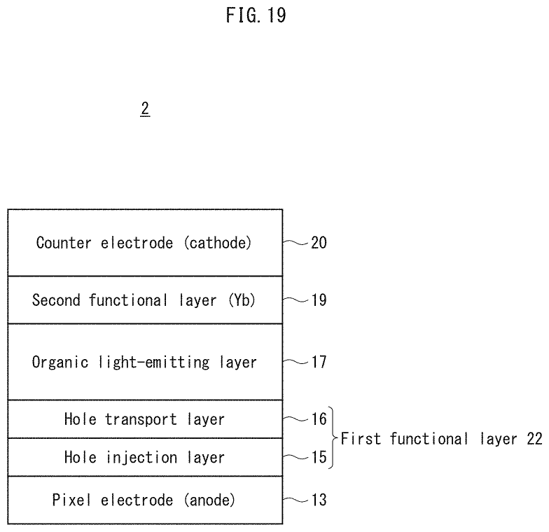

Further, in the stacked structure of the intermediate layer 18 and the second functional layer 19, the following modifications can be implemented. In the drawings from FIG. 18 onwards that illustrate the light emission section of an organic EL element, illustration of the electron donating material containing layer 171 in the organic light-emitting layer 17 is omitted for simplicity.

(2-1) As illustrated in FIG. 18, the intermediate layer 18 may be omitted and the second functional layer 19 may be formed from a mixture of NaF and Yb.

In this case the second functional layer 19 may be formed by co-deposition of NaF and Yb on the organic light-emitting layers 17, for example.

According to this structure, the second functional layer 19 itself has both an electron injection property due to Yb and property of blocking water, for example, which was originally a function of the intermediate layer 18, but the following effects can be obtained by dispersing and mixing atoms of NaF and Yb in a single layer.

When the second functional layer 19 (single layer of Yb) is stacked on the intermediate layer 18 (NaF) as illustrated in FIG. 4, the reducing action of Yb on NaF only occurs in a portion of the intermediate layer 18 in contact with the second functional layer 19, and therefore if film thickness of the intermediate layer 18 is increased, an increase in drive voltage becomes larger, and the aim of improving luminance efficiency might not be sufficiently achieved.

However, according to this modification, NaF and Yb are mixed in the second functional layer 19 by co-deposition, and therefore reduction of NaF by Yb proceeds therein, and even if film thickness is increased to some extent, the electron injection property does not easily decrease, and the second functional layer 19 can serve as an optical distance adjusting layer in the optical resonator structure. This eliminates a need to provide another film thickness adjustment layer, which simplifies manufacture (intermediate layer formation (step S7) in FIG. 13 can be omitted) and reduces production costs, while making it possible to construct the optical resonator structure to improve luminance efficiency.

Further, the Yb atoms are also distributed near the interface with the organic light-emitting layers 17, which has the benefit of facilitating diffusion into the organic light-emitting layers 17.

Further, according to at least one embodiment of this modification, a light-transmissive electrically conductive film containing a metal oxide such as an IZO film or an ITO film is disposed on the second functional layer 19.

According to at least one embodiment, an IZO film 23 is formed by a sputtering method. In general, rare earth metals such as Yb have a property of improving transparency when oxidized, but oxides are formed only on a surface of a rare earth metal body even if oxidized (passivation), as oxides densely formed on the surface block further oxidization such that inner Yb atoms do not further oxidize. However, when NaF and Yb are co-deposited, the Yb atoms and NaF molecules are dispersed as a mixture, and therefore there are gaps between Yb atoms or Yb clusters. Sputtering IZO here not only oxidizes the Yb atoms on the surface, but also allows the IZO to infiltrate through gaps between the Yb atoms and progressively oxidize the Yb atoms on the inside. As a result, even Yb atoms that are significantly deep in the film thickness direction can be oxidized, significantly improving light transmittance.

(2-2) Further, according to at least one embodiment, the second functional layer 19 is formed on the intermediate layer 18, but chemical stability of Yb is high, and therefore the intermediate layer 18 may be omitted and only the second functional layer 19 of Yb may be formed, as illustrated in FIG. 19.

Yb atoms are in direct contact with the counter electrode 20 and the organic light-emitting layers 17 across surfaces of the second functional layer 19, and therefore stability of electron injection is increased, and diffusion of Yb into the organic light-emitting layers 17 is increased. According to this embodiment, the electron donating material is Yb only.

Further, film thickness of the second functional layer is from 0.1 nm to 10 nm. As with other embodiments, if the Yb layer were less than 0.1 nm, the property of blocking water and the like would be insufficient, and a sufficient electron injection property might not be obtained. Further, if the Yb layer exceeded 10 nm, a problem with light transmission might occur, with a risk of a decrease in luminance efficiency.

According to this modification, the intermediate layer 18 is omitted, and therefore manufacture is simplified.

(2-3) Doping Organic Material with Yb to Form Second Functional Layer

### (a) Example of Uniform Yb Doping Concentration in Second Functional Layer

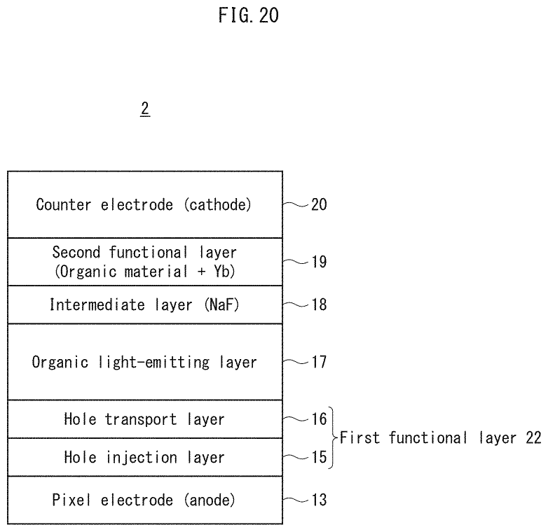

According to at least one embodiment, the second functional layer 19 is a single layer of Yb, but as illustrated in FIG. 20, the second functional layer 19 may be formed by doping an organic material with Yb.

In this case, the second functional layer 19 is formed, for example, by using a co-deposition method to form a film of an electron transporting organic material and Yb as a metal dopant across all sub-pixels.

An example of the organic material as a host of the second functional layer 19 is a n electron low molecular weight organic material such as an oxadiazole derivative (OXD), a triazole derivative (TAZ), a phenanthroline derivative (BCP, Bphen), or the like. As the metal dopant in the organic material, an alkali metal or alkaline earth metal is used. More specifically, a low work function metal such as lithium, barium, calcium, potassium, cesium, sodium, rubidium, or the like, a low work function metal salt such as lithium fluoride, a low work function metal oxide such as barium oxide, or a low work function metal organic complex such as lithium quinolinol is used.

In this case, film thickness of the second functional layer 19 can be made thicker than that of a layer of Yb alone, and therefore when an optical resonator structure is formed, a light-transmissive electrically conductive film for cavity adjustment is not required, and manufacture can be simplified.

Yb dopant concentration is a value in a range from 1 wt % to 90 wt %. As described above, Yb is more chemically stable and less likely to react with water, etc., than Ba and the like, and therefore even if dopant concentration is 1 wt %, a sufficient electron injection property can be obtained. If dopant concentration exceeds 90 wt %, lumps of Yb are likely to be generated during deposition, and it becomes difficult to evenly disperse Yb in the organic layer host material.

Further, Yb has a superior light transmittance to Ba and the like, and therefore does not affect light transmittance of the second functional layer so much and good luminance efficiency can be maintained.

Yb can be a high concentration dopant in this way, and therefore an electron injection property can be stably maintained for a longer period of time, which can contribute to further life extension. Further, the range of dopant concentration is wide, and therefore a range of film thickness of the organic host material of the second functional layer 19 can be wide, increasing a degree of freedom in designing the optical resonator structure.

### (b) Example of Yb Concentration Gradient in Film Thickness Direction of Second Functional Layer

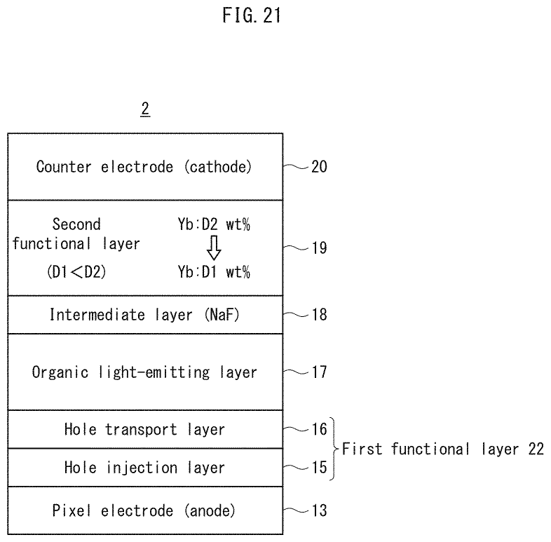

As illustrated in FIG. 21, when Yb dopant concentration of the second functional layer 19 on a side in contact with the counter electrode 20 is D2 wt %, and decreases as distance to the intermediate layer 18 decreases, Yb dopant concentration of a portion of the second functional layer 19 in contact with the intermediate layer 18 is D1 wt %, where D1<D2.

This continuous change in Yb content of the second functional layer 19 means that while the NaF of the intermediate layer 18 provides water resistance, a weak reducing property acts on the intermediate layer 19, an electron injection property is limited, entry of impurities into the second functional layer is further suppressed, and light transmittance is prevented from being reduced more than necessary by an increase in Yb dopant. Further, by increasing cathode-side concentration, electron injection from the cathode side to the functional layer can be improved, and entry of impurities from outside can be prevented to further extend life of an organic EL element.

Thus, an organic EL element can be provided that has a higher luminance efficiency and longer life.

As a method of generating a gradual gradient of Yb concentration, an example is to use a co-deposition method in which a temperature of an electric furnace for heating Yb and a temperature of an electric furnace for heating organic material are each controlled to reduce a deposition rate of Yb relative to a deposition rate of the organic material.

### (c) Example of Second Functional Layer as Two-Layer Structure

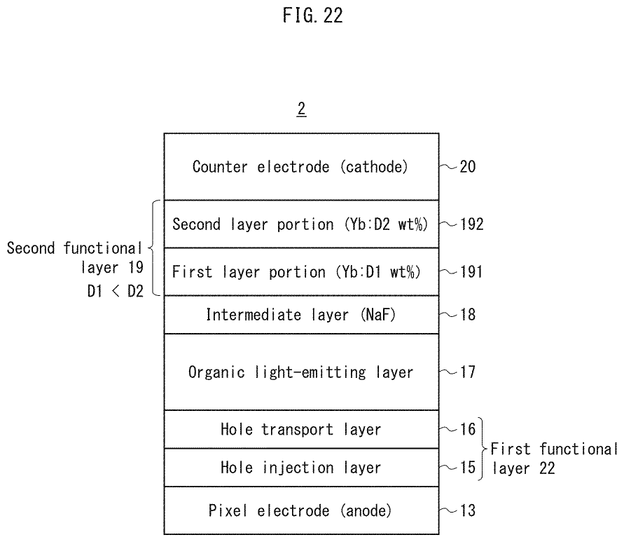

As illustrated in FIG. 22, the second functional layer 19 may be two-layer structure of a first layer portion 191 and a second layer portion 192, where Yb dopant concentration of the second layer portion 192 (D2 wt %) is higher than Yb dopant concentration of the first layer portion 191 (D1 wt %) (D1<D2).

### (d) Example of Second Functional Layer as Three-Layer Structure

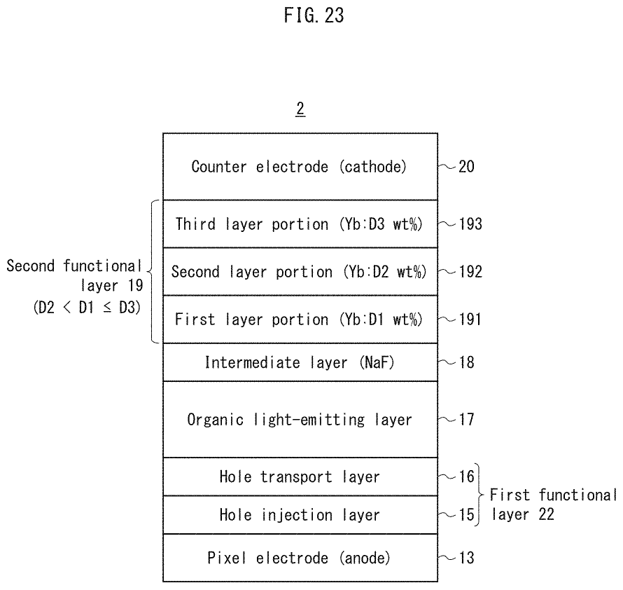

Further, as illustrated in FIG. 23, the second functional layer 19 may be a three-layer structure of the first layer portion 191, the second layer portion 192, and a third layer portion 193, where Yb dopant concentrations of the layer portions are D1 wt %, D2 wt %, and D3 wt %, respectively, and satisfy a relationship D2<D1≤D3.

According to this modification, the dopant concentration of the third layer portion 193 on the counter electrode 20 side is higher than that of the first layer portion 191 on the intermediate layer 18 side, so this structure achieve the same effects as the modifications described above. Further, the dopant concentration of the second layer portion 192 between the first layer portion 191 and the third layer portion 193 is set to be lowest, and therefore light transmission is not decreased any more than necessary by an increase in Yb dopant. The first layer portion 191 makes it possible to improve electron injection towards the light-emitting layer while the NaF in the intermediate layer exhibits a waterproofing property.

Further, by increasing concentration of the third layer portion 193, electron injection from the cathode side towards the light-emitting layer can be improved, and entry of impurities from outside can be prevented to further extend life of an organic EL element.

(3) In the organic EL display panel 10 according to at least one embodiment, as illustrated in FIG. 2, a direction of extension of the pixel regulation layers 141 is a long axis X direction of the organic EL display panel 10, and a direction of extension of the banks 14 is a short axis Y direction of the organic EL display panel 10, but extension directions of the pixel regulation layers 141 and the banks 14 may be switched. Further, directions of extension of the pixel regulation layers 141 and the banks 14 may be any directions regardless of the shape of the organic EL display panel 10.

Further, in the organic EL display panel 10 according to at least one embodiment, the image display surface is rectangular, but the shape of the image display surface is not limited to this example and may be changed as appropriate.

Further, in the organic EL display panel 10 according to at least one embodiment, the pixel electrodes 13 are each a rectangular flat plate-shape, but the pixel electrodes 13 are not limited to this example.

According to at least one embodiment, the organic EL display panel is a line bank type of display panel, but the display panel may be a pixel bank type in which banks surround each sub-pixel in four directions.

In a line bank type of display panel, material of the light-emitting layers remains on the pixel regulation layers 141, and therefore an amount of ink applied is larger than in a pixel bank type of display panel, and an amount of water remaining after drying is larger, and therefore an effect of adopting liquid-resistant Yb as the metal dopant of the second functional layer 19 is greater.

(4) According to at least one embodiment, the hole injection layers 15, the hole transport layers 16, and the organic light-emitting layers 17 are formed by printing methods (application methods), but only one of these layers need be an applied film formed by a printing method. In a finished product of the organic EL display panel 10, whether or not a specific layer is an applied film can be easily determined by detecting water and solvent remaining in the film.

(5) According to at least one embodiment, the hole injection layers 15 are formed by a printing method using an ink including an electrically conductive polymer material, but the hole injection layers 15 may be formed by deposition or sputtering of an oxide of a transition metal. When the hole injection layers 15 include a transition metal oxide, multiple valences and multiple energy levels can be taken. As a result, hole injection is facilitated, and a reduction in drive voltage becomes possible. Tungsten oxide is appropriate as such a metal oxide.

As a result, a hole injection amount can be increased in accordance with an increase in an electron injection amount due to the electron donating material containing layer 171, carrier balance can be achieved in a state of increased exciton amount, and further improvement to luminance efficiency can be expected.

In this case, a metal material layer of the pixel electrodes and a layer of tungsten oxide may be stacked, then a photolithography method and etching method used for patterning to form the pixel electrodes 13 and the hole injection layers 15 at the same time, and the banks 14 and the pixel regulation layers 141 formed subsequently, thereby simplifying manufacture.

(6) In the organic EL display panel 10 according to at least one embodiment there are the sub-pixels 100R, 100G, 100B that emit R, G, B colors of light, respectively, but light-emission colors of the sub-pixels are not limited to this example. For example, yellow (Y) may be used in addition to R, G, B. Further, in one pixel P, the number of sub-pixels of one color is not limited to one, and there may be two or more. Further, arrangement of sub-pixels in a pixel P are not limited to a sequence R, G, B as illustrated in FIG. 2, and may be in a different sequence.

(7) The organic EL panel 10 according to at least one embodiment is an active matrix type, but the organic EL display panel 10 is not limited to this example and may be a passive matrix type.

Further, the organic EL display panel 10 is not limited to being a top-emission type of display panel, and may be a bottom-emission type of display panel.

In the case of a bottom-emission type of display panel, the counter electrode 20 is a light-reflective anode, and the pixel electrodes 13 are made of a light-transmissive material to serve as cathodes. In addition, an order of stacking the first functional layer 22, the intermediate layer 18, the second functional layer 19, etc., will be different.

What is claimed is:

1. An organic electroluminescence (EL) element comprising:
an anode;
a first functional layer disposed on or above the anode, the first functional layer having at least one of a property of facilitating hole injection and a property of facilitating hole transportation;
a light-emitting layer disposed on or above the first functional layer, the light-emitting layer including an organic light-emitting material doped with an electron donating material;
a second functional layer disposed on or above the light-emitting layer, the second functional layer including a rare earth metal; and
a cathode disposed on or above the second functional layer.

2. The organic EL element of claim 1, wherein the rare earth metal is Yb.

3. The organic EL element of claim 1, wherein the electron donating material includes one or more metals selected from the group consisting of alkali metals, alkaline earth metals, and rare earth metals.

4. The organic EL element of claim 3, wherein the electron donating material includes Na.

5. The organic EL element of claim 3, wherein the electron donating material includes Yb.

6. The organic EL element of claim 1, wherein the second functional layer is in direct contact with the light-emitting layer.

7. The organic EL element of claim 1, further comprising an intermediate layer disposed between the light-emitting layer and the second functional layer, the intermediate layer including a metal compound, the metal of the metal compound being selected from the group consisting of alkali metals and alkaline earth metals.

8. The organic EL element of claim 1, wherein in a film thickness direction of the light-emitting layer, a first region of the light-emitting layer is a region nearest the first functional layer and a second region of the light-emitting layer is a region nearest the second functional layer, and a ratio of the electron donating material to the organic light-emitting material in the first region is smaller than a ratio of the electron donating material to the organic light-emitting material in the second region.

9. The organic EL element of claim 8, wherein a carrier density in the second region of the light-emitting layer is from 10¹²/cm³ to 10¹⁹/cm³.

10. The organic EL element of claim 8, wherein a density of excitons generated in the light-emitting layer is higher in the first region than in the second region.

11. The organic EL element of claim 1, wherein the cathode is light-transmissive.

12. The organic EL element of claim 1, wherein film thickness of the light-emitting layer is from 30 nm to 150 nm.

13. The organic EL element of claim 1, wherein at least one layer selected from the group consisting of the light-emitting layer and the first functional layer is a film applied by a wet process.

14. The organic EL element of claim 1, wherein the first functional layer includes tungsten oxide.

15. An organic electroluminescence (EL) display panel comprising:
a substrate;
organic EL elements arranged on or above the substrate in a matrix of rows and columns; and
banks arranged on or above the substrate that extend in a column direction, wherein
each of the organic EL elements comprises:
an anode;
a first functional layer disposed on or above the anode, the first functional layer having at least one of a property of facilitating hole injection and a property of facilitating hole transportation;
a light-emitting layer disposed on or above the first functional layer, the light-emitting layer including an organic light-emitting material doped with an electron donating material;
a second functional layer disposed on or above the light-emitting layer, the second functional layer including a rare earth metal; and
a cathode disposed on or above the second functional layer, and
the banks separate the light-emitting layers of the organic EL elements in a row direction.

16. An organic electroluminescence (EL) element manufacturing method comprising:
forming an anode;
forming a first functional layer on or above the anode, the first functional layer having at least one of a property of facilitating hole injection and a property of facilitating hole transportation;
forming an organic light-emitting material layer on the first functional layer, the organic light-emitting material layer being made of an organic light-emitting material;
forming an intermediate layer on the organic light-emitting material layer, the intermediate layer including a metal compound including a first metal selected from the group consisting of alkali metals and alkaline earth metals;
forming a second functional layer on the intermediate layer, the second functional layer including a second metal that is a rare earth metal; and
forming a cathode on or above the second functional layer, wherein
an electron donating material containing layer is formed from a portion of the organic light-emitting material layer by diffusion of the first metal, or the first metal and the second metal, into the organic light-emitting material layer until a carrier density in the portion of the organic light-emitting material layer is from 10¹²/cm³ to 10⁹/cm³.

17. The manufacturing method of claim 16, wherein the metal compound is NaF.

18. The manufacturing method of claim 16, wherein the second metal is Yb.

19. An organic electroluminescence (EL) element manufacturing method comprising:
forming an anode;
forming a first functional layer on or above the anode, the first functional layer having at least one of a property of facilitating hole injection and a property of facilitating hole transportation;
forming an organic light-emitting material layer on the first functional layer, the organic light-emitting material layer being made of an organic light-emitting material;
forming a second functional layer on the organic light-emitting material layer, the second functional layer including a rare earth metal; and
forming a cathode on or above the second functional layer, wherein
an electron donating material containing layer is formed from a portion of the organic light-emitting material layer by diffusion of the first metal, or the first metal and the second metal, into the organic light-emitting material layer until a carrier density in the portion of the organic light-emitting material layer is from 10¹²/cm³ to 10¹⁹/cm³.

20. The manufacturing method of claim 19, wherein the rare earth metal is Yb.
